(19) United States
(12) Patent Application Publication
(10) Pub. No.: US 2005/0260790 A1
(43) Pub. Date: Nov. 24, 2005

(54) Substrate imprinting techniques

(76) Inventors: Michael D. Goodner, Hillsboro, OR (US); Paul A. Koning, Chandler, AZ (US); James Christopher Matabayas JR., Chandler, AZ (US); Robert P. Meagley, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/853,307

(22) Filed: May 24, 2004

(51) Int. Cl. H01L 21/44; H01L 21/48

(52) U.S. Cl. 438/106; 438/127; 438/126

(57) ABSTRACT

A method of making an electronics substrate is provided. A material is deposited on a base component. The material has a first composition and includes a polymer. A pattern is imprinted into the material by contacting the material with a die and moving a profile of the die into the material. The material is then modified while being held in the profile of the die to cause at least partial curing of the material due to a change in composition of the material from a first composition to a second composition. The die is then removed from the material. Electric conductors are then formed in trenches of the pattern.

### BACKGROUND OF THE INVENTION

1). Field of the Invention

This invention relates generally to a method of making an electronics substrate, and more specifically to substrate imprinting techniques.

2). Discussion of Related Art

The current state of the art for substrate manufacture utilizes a thermosetting epoxy dielectric film upon which a layer of copper is plated. The circuitry is obtained by use of a sacrificial photo-definable layer, which after being developed serves as the mask for etching the exposed copper and dielectric material. The photo-definable layer is then removed.

Imprinting technology is being developed using a thermosetting epoxy dielectric film. Previous pathfinding efforts showed that thermoplastic materials do not allow simple construction of multilayer substrates. This is due to lack of sufficiently different Tg grades for each package layer and deformation/distortion of lower layers when new top layers are laminated on. Lamination adhesives can be used, but degrade overall package performance.

Imprinting technology is being evaluated as a next generation process for manufacturing substrates. Current state of the art epoxy dielectric film materials do not cure under typical imprinting processes (e.g., 165° C. maximum temperature for 1 minute), and during a prolonged subsequent thermal cure (e.g., 170° C. for 90 minutes) the imprinted features are lost or very degraded. For manufacture of substrates by imprinting, the dielectric film is imprinted at a pressure of 300 psi for about 1 minute, during which time the temperature is rapidly ramped to 165° C. and then decreased to about 100° C. The temperature must be decreased due to the low molecular weight material sticking to the micro tool at an elevated temperature. Post imprinting, the film is cured at about 170° C. for 90 minutes, during which time many of the features are lost or distorted due to material flow prior to achieving sufficient cure. To avoid the problem of lost features, the film can be partially cured prior to imprinting; however, this leads to poor images in the film—the imprinted features are not as deep and well-defined. The imprinting process can be extended to provide 5 to 15 minutes at 165° C.; however, such long imprinting times are not feasible for HVM manufacturing due to cost and throughput (UPH) concerns.

Next generation substrate materials need to be: (a) low CTE, to enable Low k ILD and 6+ stacking of microvias; (b) tough, to resist cracking; and (c) low k, to enable smaller line and spacing. Current epoxy technology is being challenged by these performance demands. Engineering polymers can meet these demands, but have not been optimized for substrate assembly application.

Common engineering polymers only exist in a limited number of glass transition (Tg) grades. This means that in a 4 to 12 layer package, unless you have 4 to 12 Tg grades of polymer, you risk deforming underlying features when you heat the package up to laminate each outer layer.

### BRIEF DESCRIPTION OF THE DRAWINGS

The invention is described by way of examples with reference to the accompanying drawings, wherein:

FIG. 1A is a cross-sectional side view illustrating a base component and two layers of moldable material that are placed on the based component;

FIG. 1B is a view similar to FIG. 1A, further illustrating two dies having profiles for imprinting into the material;

FIG. 1C is a view similar to FIG. 1B, after imprinting of the material with the dies;

FIG. 1D is a view similar to FIG. 1C, after the material is hardened while still in contact with the dies;

FIG. 1E is a view similar to FIG. 1D, after the dies are removed;

FIG. 1F is a view similar to FIG. 1E, after a thin metal layer is formed on the hardened material;

FIG. 1G is a view similar to FIG. 1F, after a thick metal layer is plated on the thin metal layer; and

FIG. 1H is a view similar to FIG. 1G, after the thick metal layer is planarized.

### DETAILED DESCRIPTION OF THE INVENTION

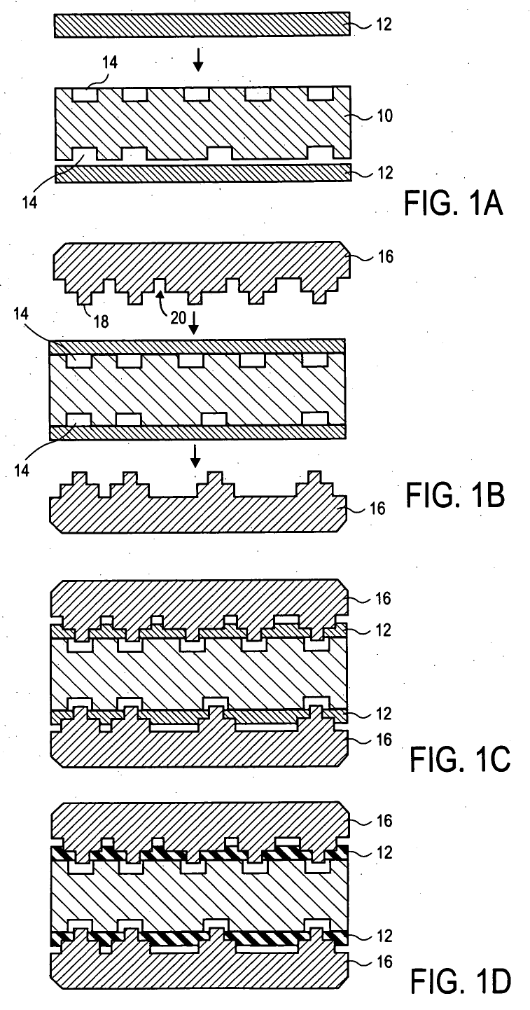

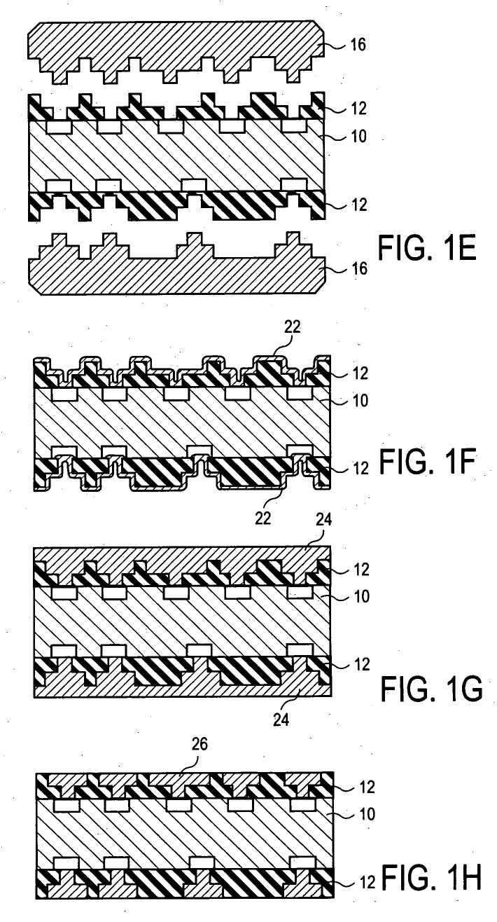

FIGS. 1A to 1H illustrate one of multiple cycles in the manufacture of an electronics substrate of the kind to which a microelectronic die can be mounted. A material on the substrate is imprinted (FIG. 1C), and the material is then at least partially cured (FIG. 1D) while still in contact with a die, so that the shape and profile of the material can be maintained.

FIG. 1A illustrates a base component 10 and layers of soft, moldable material 12. The base component 10 has a plurality of trenches 14 formed therein. The material 12 is located on upper and lower surfaces of the base component 10 and over the trenches 14.

FIG. 1B illustrates the components of FIG. 1A after the material 12 is placed on the base component 10, and further illustrates imprinting dies 16. Each die 16 has a profile with a plurality of raised and recessed formations 18 and 20, respectively.

As illustrated in FIG. 1C, the dies 16 are moved into contact with the material 12, and a force is applied that imprints the profile of the dies 16 into the material 12. Outer surfaces of the material 12 then acquire a shape that corresponds to the profile of the respective die 16. The trenches 14 allow for raised formations 18 of the die 16 to penetrate almost entirely through the material 12. The material 12 is, at this stage, suitably soft to allow for imprinting of a shape therein.

As illustrated in FIG. 1D, the material 12 is subsequently modified while being held in the profile of the respective die 16. By modifying the material 12, at least partial curing of the material 12 is accomplished due to a change in composition of the material 12 from a first composition to a second composition. Numerous mechanisms can be employed to harden the material 12, as will be discussed herein.

As illustrated in FIG. 1E, the dies 16 are subsequently removed from the hardened material 12. FIG. 1F illustrates the structure of FIG. 1E, after a thin metal layer 22 is sputtered or otherwise deposited over the hardened material 12. As illustrated in FIG. 1G, a thick metal layer 24 is subsequently plated or otherwise deposited on the thin metal layer 22. As further illustrated in FIG. 1H, the thick metal layer 24 is subsequently planarized to leave metal conductors 26, only within trenches defined in the hardened material 12.

The process of FIGS. 1A to 1H may then be repeated, with the structure of FIG. 1H acting as the base component. Ideally, the same material as the material 12 should be used for each subsequent cycle, and the temperature profile should be the same if a thermal cure is employed.

Substrate Imprinting Using Non-Reactive Engineering Polymers

In one embodiment, a material including an engineering polymer and a solvent or plasticizer can be used. By using a plasticized engineering polymer, no chemical cure is required. After a short thermal treatment to remove solvent and/or plasticizer (a physical cure process), the engineering polymer will not require an extended chemical cure (thus retaining feature integrity) and have thermomechanical properties equivalent to or greater than current substrates due to the robust nature of engineering polymers. Further, throughput is increased, due to reduced imprinting time and elimination of post-imprinting cure time, which means that cost is reduced. In addition, because the image will be imparted by an imprinting process rather than lithographic process, the dielectric material does not require developing characteristics. Lastly, since the Tg of the polymer increases by removal of the solvent or plasticizer, the same grade of polymer can be used for all package layers, without risking distortion of underlying features.

Spin-coatable and screen-printable engineering polymers are currently available commercially (examples include block polyimides from PI R&D, as well as other pre-imidized polyimides from Amoco and Nippon-Zeon). These materials are used in either direct photodefinable or dry etch patterning processes and show the ability to hold features permanently after the features are formed and the carrier solvent is removed. A hot embossing process will yield similar results, and other spin-coatable and screen-printable engineering polymers other than polyimides may be used in a similar manner as described below.

In this embodiment of the invention, a blend of an engineering polymer and a solvent or plasticizer as the dielectric layer is used in the imprinting process of FIG. 1. Because the solvent or plasticizer can be removed using modest thermal treatment, no chemical cure is required after imprinting. The material requirements are dielectric constant less than 3.4 (@ 1 GHz), CTE less than 60 ppm/° C., modulus between about 1 and 4 GPa, and sufficient stability to withstand preconditioning (including 5× reflows to 260° C.). It is also advantageous to have a Tg above the imprinting temperature, to prevent flow of underlying layers while imprinting subsequent layers. Several classes of engineering polymers have these properties, as shown in Table 1, including polyimides, which are widely used in the semiconductor industry as buffer coating materials and redistribution layers. Other classes of candidate polymers not shown in Table 1 include polybenzimide, polybenzoxazole, polycarbonate, polyurethane, polyphosphazene, polyetherketone, polyarylate, polycyclopentadiene, polynorbornene, polynortricyclene, and other cycloaliphatic polymers. Furthermore, blends of these polymer as well as copolymers can be used to achieve the desired material properties.

TABLE 1
Properties of Candidate Engineering Polymers

| Polymer | k | CTE (ppm/C.) | E (GPa) | Tg (C.) | Tmax (C.) |
|---|---|---|---|---|---|
| (Desired Range) | <3.4 | <60 | 1-4 | >150 | >260 |
| Polyimide (PI) | 2.9-3.3 | 5-60 | 1-6 | 270-350 | >400 |
| Polybenimidzaole (PBI) | 3.2 | 23 | 5.9 | 400 | 260-400 |
| Polyetherimide (PEI) | 2.8-3.7 | 16-56 | 2.7-6.4 | 215-220 | 220 |
| Polycarbonate | 2.9-3.0 | 32-120 | 1.6-2.4 | 150 | 154 |
| Polysulfone | 3-3.2 | 55-100 | 2.5-2.7 | 188-190 | 190 |
| Polyethersulfone (PES) | 3.5-4.1 | 31-70 | 2.4-8.6 | 230 | 220 |
| Polyketone | 3.7-5.8 | 8-110 | 1.5-18.6 | 155 | 220 |
| Polyetheretherketone (PEEK) | 3.2-3.45 | 40-47 | 3.1-8.3 | 140-177 | 334 |
| Polyphenlyene oxide (PPE) | 2-3 | 50-100 | 2-5.4 | 120-140 | 250 |

Note:
Properties are “typical” for the class of materials, but variations may be found based upon actual chemical composition.
k—dielectric constant
CTE—Coefficient of thermal expansion
E—modulus
Tg—glass transition temperature
Tmax—maximum service temperature (minimum of melting temperature and decomposition temperature)

The choice of solvent or plasticizer depends on the polymer(s) selected. Common solvent and plasticizers include toluene, xylene, anisole, pyridine, N-methyl-pyrrolidinone (NMP), N,N-dimethylacetamide, N,N-dimethylformamide, cyclohexanone, tetrahydrofuran, cyclohexyl-2-pyrrolidone, and water. Plasticizers with high enough vapor pressure (or low enough boiling point) to be removed in processing include alkyl, halo and alkoxyderivatives of benzene, alkanes, haloalkanes, ethers, and esters (both branched and straight chain). There may also be advantage in using a blend of solvents and/or plasticizers to achieve maximum depression of the glass transition temperature and a minimization of voiding (by gradual evolution of the plasticizer using solvents with a range of boiling points).

The engineering polymer is thus co-deposited with a solvent or plasticizer to facilitate deformation and embossing during the imprinting process. During imprinting, the polymer resin preferably has some ability to flow to conform to the profile of the die. To achieve this, the resin should have viscosity less than about 250,000 poise prior to imprinting. Because of their high strength and resistance to deformation, engineering polymers cannot usually be utilized for this application. Upon the addition of a solvent or other plasticizing agent, however, the material becomes workable as long as the plasticizer is present. By controlling the temperature of the die and the ultrasonic energy density, a material could be worked into conformation with the pattern on the head prior to or during plasticizer loss. Then, by increasing the thermal or ultrasonic energy input, the remainder of the plasticizer can be driven off, leaving the polymer in the desired pattern.

Alternate methods of imprinting and solvent/plasticizer removal are possible: (a) a simple heated microtool may be sufficient to remove the solvent; (b) the entire imprinting process may be run under vacuum; (c) the imprinted film may be placed in a heated vacuum oven post imprinting to facilitate solvent removal; or (d) the imprinted sample may be exposed to microwaves to facilitate solvent removal; or (e) extraction by supercritical carbon dioxide. The exact temperature and energy inputs would be determined as a function of polymer workability while plasticized, the overall content of plasticizer(s), and the loss rate of the plasticizer(s) (as determined by vapor pressure, etc.). After the plasticizer is driven off, the engineering polymer will have sufficient thermomechanical properties to retain its shape and structure during subsequent processing steps, including additional imprinting of additional polymer layers. It is advantageous to use an engineering polymer in the amorphous phase, to reduce defects such as crazing or cracking. Control of crystallinity may be realized through proper choice of polymer side chains as well as tuning the polydispersity of the polymer (broader polydispersity, multimodal polydispersity, etc.).

As an example of a potential embodiment of this invention, the following system could be realized: a 50 micron thick sheet of polyetherimide is dip-coated in a blend of cyclohexyl-2-pyrrolidone, NMP, and water to achieve an approximately 5 wt % residual solvent in the film. This film is then laminated onto a substrate core at 180° C. (35° C. below its “dry” Tg of 215° C.). This laminated core is then imprinted at 195° C. for 1 minute to impart the trenches of the pattern, including the lines, traces, and microvia features. The cores are then passed on to a microwave drying oven to reduce the solvent content to under 0.2 wt %. The cores are then passed through an industry standard copper plating and planarization process. The next layer of polymer and solvent is laminated on top of the structure at 180° C. and imprinted at 195° C. with no distortion of the lower layer, which has a Tg of 215° C.

The dielectric material may also comprise other commonly used components, including fillers, adhesion promoters, mold release agents, surfactants, colorants, stabilizers, anti-oxidants, flame retardants, film forming additives, and similar additives known to those skilled in the art.

Substrate Imprinting Using Engineering Polymers and Reactive Solvents

In another embodiment, a material including an engineering polymer and a reactive solvent or plasticizer can be used. By using a reactive solvent to plasticize an engineering polymer, the imprinting process can be completed with a less aggressive chemical cure process than is currently required for the epoxy dielectrics, thus retaining feature integrity and yielding a film having thermomechanical properties equivalent to or greater than current substrates due to the robust nature of engineering polymers. Further, throughput is increased, due to reduced imprinting time and elimination of post-imprinting cure time, which means that cost is reduced. In addition, because the image will be imparted by an imprinting process rather than a lithographic process, the dielectric material does not require developing characteristics. Lastly, since the Tg of the film increases by curing (as well as possible removal) of the solvent or plasticizer, the same grade of polymer can be used for all package layers, without risking distortion of underlying features.

In this embodiment of the invention, a blend of an engineering polymer and a reactive solvent or plasticizer (hereafter referred to as “reactive solvent”) as the dielectric layer is used in the imprinting process of FIG. 1. The engineering polymer is co-deposited with the reactive solvent to facilitate deformation and embossing during the imprinting process, then curing the reactive solvent to set the material. During imprinting, the polymer resin must have some ability to flow to conform to the profile of the imprinting head. To achieve this, the resin should have viscosity less than about 250,000 poise prior to imprinting. Because of their high strength and resistance to deformation, engineering polymers cannot usually be utilized for this application. Upon the addition of a solvent to act as a plasticizing agent, the material becomes workable. By controlling the temperature of the die and the ultrasonic energy density, a material could be worked into conformation with the pattern on the head prior to or during the reactive solvent curing (in which the solvent reacts to form a polymer or other solid material). At the end of the imprinting process, the thermal or ultrasonic energy input can be increased, causing the remainder of the reactive solvent to cure and leaving the polymer in the desired pattern. Alternatively, a post-imprinting treatment step can be added in which the material is briefly exposed to high temperature to initiate a thermal cure reaction, or exposed to radiation to initiate a photochemical cure reaction. In either case, the use of low-temperature thermal initiators or photoinitiators can facilitate low-temperature rapid curing of the system during or after imprinting. By reducing the chemical cure time and/or temperature, increased throughput (due to reduced processing time) and increased resolution/feature integrity (due to minimization of high temperature steps which can cause feature reflow) may be realized. After the reactive solvent is cured, the system formed by the engineering polymer and reacted solvent will have sufficient thermomechanical properties to retain its shape and structure during subsequent processing steps, including additional imprinting of additional polymer layers.

The material requirements for a substrate dielectric are dielectric constant less than 3.4 (@1 GHz), CTE less than 60 ppm/° C., modulus between about 1 and 4 GPa, and sufficient stability to withstand preconditioning (including 5× reflows to 260° C. It is also advantageous to have a Tg above the imprinting temperature, to prevent flow of underlying layers while imprinting subsequent layers. Several classes of engineering polymers have these properties, as shown in Table 1, including polyimides, which are widely used in the semiconductor industry as buffer coating materials and redistribution layers. Other classes of candidate polymers not shown in Table 1 include polybenzimide, polybenzoxazole, polycarbonate, polyurethane, polyphosphazene, polyetherketone, polyarylate, polycyclopentadiene, polynorbornene, polynortricyclene, and other cycloaliphatic polymers. Furthermore, blends of these polymers as well as copolymers can be used to achieve the desired material properties. It should be noted that while the presence of the cured reactive solvent can lead to Tg depression, if a crosslinking reactive solvent is chosen, a semi-interpenetrating network (semi-IPN) will be formed that will not flow during subsequent thermal treatments, thereby relaxing the Tg requirement and expanding the list of engineering polymers that can be used. Also, it is advantageous to use an engineering polymer in the amorphous phase, to reduce defects such as crazing or cracking. Forming semi-IPNs or in situ polymer blends (if the reactive solvent forms a linear polymer upon cure), crystallinity will effectively be reduced compared to conventional systems.

The choice of reactive solvent depends primarily on two factors: ability to solvate the engineering polymer and any additives (such as initiators) and the structure formed upon cure. Examples of reactive solvents would be styrene, alpha-methyl styrene, and divinyl benezene, which form polystyrene and its analogues upon curing (with polystyrene having a decomposition temperature of 260° C. or above). More general classes of reactive solvents include vinyl ether, an alpha-olefin, a sytrenic, and an acrylate, etc. (Table 2), with selection of a particular reactive solvent depending on the two factors cited above. The thermal or photoinitiator must be chosen based upon the reaction mechanism (anionic, cationic, or free radical, per Table 2); however, a wide variety of these materials and their properties are available in the public domain, and their application to this invention will be apparent to those skilled in the art. Common examples include 2,2-dimethoxy-2-phenylacetophenone (a radical photoinitiator) and 2,2′-azo-bis(isobutyronitrile) (a thermal radical initiator).

TABLE 2
Chain Polymerization Mechanisms
Types of Chain Polymerization
Undergone by Various Unsaturated Monomers

| | Type of Initiation | | |
|---|---|---|---|
| Monomers | Radical | Cationic | Anionic |
| 1-Alkyl olefins (α olefins) | − | + | − |
| 1,1-Dialkyl olefins | − | + | − |
| 1,3-Dienes | + | + | + |
| Styrene, α-methyl styrene | + | + | + |
| Halogenated olefins | + | − | − |
| Vinyl esters (CH₂═CHOCOR) | + | − | − |
| Acrylates, methacrylates | + | − | + |
| Acrylonitrile, methacrylonitrile | + | − | + |
| Acrylamide, methacrylamide | + | − | + |
| Vinyl ethers | − | + | − |
| N-Vinyl carbazole | + | + | − |
| N-Vinyl pyrrolidone | + | + | − |
| Aldehydes, ketones | − | + | + |

The dielectric material described by this invention may also comprise other commonly used components, including fillers, adhesion promoters, mold release agents, surfactants, colorants, stabilizers, anti-oxidants, flame retardants, film forming additives, and similar additives known to those skilled in the art.

Substrate Imprinting Using Reactive Engineering Polymers

In a further embodiment, a material including an engineering polymer with reactive functional groups can be used. By using an engineering polymer with reactive functional groups, the imprinting process can be completed with a less aggressive chemical cure process than is currently required for the epoxy dielectrics-thermal free radical initiators can initiate cure at temperatures as low as 50° C., and photoinitiators can initiate cure at room temperature. By avoiding high temperatures during the cure process, there is less opportunity for the imprinted pattern to reflow, thus the invention results in better feature definition and better resolution. Also, the use of engineering polymers as the main component of the system provides improved thermomechanical properties compared to epoxy dielectrics due to the robust nature of engineering polymers. Further, throughput is increased, due to reduced imprinting time and significant reduction of post-imprinting cure time, which means that cost is reduced. In addition, because the image will be imparted by an imprinting process rather than a lithographic process, the dielectric material does not require developing characteristics. Lastly, since a high Tg engineering polymer can be used in conjunction with the formation of a crosslinked network upon cure, increased Tg systems can be achieved and the same grade of polymer can be used for all package layers, without risking distortion of underlying features.

Spin-coatable and screen-printable telechelic (end-functionalized with reactive groups) engineering polymers are have been developed for use in the semiconductor industry, such as the Amoco Ultradel™ series of acrylate-functionalized pre-imidized polyimides. These materials are used in either direct photodefinable or dry etch patterning processes and show the ability to hold features permanently after the features are formed and the carrier solvent is removed. It is reasonable to expect that in A hot embossing process will yield similar results, and other spin-coatable and screen-printable engineering polymers other than polyimides may be used in a similar manner as described below.

In this embodiment of the invention, a blend of an engineering polymer with reactive functional groups and a solvent or plasticizer as the dielectric layer is thus used in the imprinting process of FIG. 1. The engineering polymer is co-deposited with the solvent to facilitate deformation and embossing during the imprinting process, then evaporating the solvent and reacting (curing) the polymer functional groups to set the material. During imprinting, the polymer resin preferably has some ability to flow to conform to the profile of the imprinting head. To achieve this, the resin should have viscosity less than about 250,000 poise prior to imprinting. Because of their high strength and resistance to deformation, engineering polymers cannot usually be utilized for this application. Upon the addition of a solvent to act as a plasticizing agent, the material becomes workable. By controlling the temperature of the imprinting horn and the ultrasonic energy density, a material could be worked into conformation with the pattern on the head prior to or during solvent evaporation and polymer curing. At the end of the imprinting process, the thermal or ultrasonic energy input can be increased, causing the majority of the solvent to evaporate the reactive groups to cure, leaving the polymer in the desired pattern. Alternatively, a post-imprinting treatment step can be added in which the material is briefly exposed to high temperature to initiate a thermal cure reaction, or exposed to radiation to initiate photochemical curing. In either case, the use of low-temperature thermal initiators or photoinitiators can facilitate low-temperature rapid curing of the system during or after imprinting. By reducing the chemical cure time and/or temperature, increased throughput (due to reduced processing time) and increased resolution/feature integrity (due to minimization of high temperature steps which can cause feature reflow) may be realized. After the material is cured and the solvent evaporated, the system formed by the reacted engineering polymer will have sufficient thermomechanical properties to retain its shape and structure during subsequent processing steps, including additional imprinting of additional polymer layers.

The material requirements for a substrate dielectric are dielectric constant less than 3.4 (@ 1 GHz), CTE less than 60 ppm/° C., modulus between about 1 and 4 GPa, and sufficient stability to withstand preconditioning (including 5× reflows to 260° C.). It is also advantageous to have a Tg above the imprinting temperature, to prevent flow of underlying layers while imprinting subsequent layers. Several classes of engineering polymers have these properties, as shown in Table 1, including polyimides, which are widely used in the semiconductor industry as buffer coating materials and redistribution layers. Other classes of candidate polymers not shown in Table 1 include polybenzimide, polybenzoxazole, polycarbonate, polyurethane, polyphosphazene, polyetherketone, polyarylate, polycyclopentadiene, polynorbornene, polynortricyclene, and other cycloaliphatic polymers. Furthermore, blends of these polymers as well as copolymers can be used to achieve the desired material properties. To be used in this embodiment of the invention, these polymers should be functionalized with reactable groups either at the end (telechelic polymers), in the polymer backbone, or on sidegroups. Depending on the functional group, upon reaction the system may form a crosslinked network (if the polymer chains react in more than one place) or branched polymer system (only one reaction site per chain). It should be noted that a crosslinked system has the advantage of not flowing during subsequent thermal treatments, thereby relaxing the Tg requirement and expanding the list of engineering polymers that can be used. One preferred embodiment would be a telechelic polyimide, as these systems have been previously demonstrated (Amoco Ultradel™), although a styrenic endgroup may be preferable to maintain a high decomposition temperature.

The choice of solvent or plasticizer depends on the polymer(s) selected. Common solvents include xylene, toluene, anisole, pyridine, N-methyl-pyrrolidinone (NMP), N,N-dimethylacetamide, N,N-dimethylformamide, cyclohexanone, tetrahydrofuran, cyclohexyl-2-pyrrolidone and water. Plasticizers with high enough vapor pressure (or low enough boiling point) to be removed in processing include alkyl, halo and alkoxy derivatives of benzene, alkanes, haloalkanes, ethers, and esters (both branched and straight chain). It would also be possible to choose a reactive solvent (such as styrene, a-methyl styrene or divinyl benzene) that will cure in conjunction with the functionalized polymer. More general classes of reactive solvents are outlined above in the discussion of an embodiment using reactive solvents with unreactive polymers.

The thermal or photoinitiator should be chosen based upon the reaction mechanism (anionic, cationic or free radical, per Table 2) for reaction; however, a wide variety of these materials and their properties are available in the public domain, and their application to this invention will be apparent to those skilled in the art. Examples include 2,2-dimethoxy-2-phenylacetophenone (a common radical photoinitiator) and 2,2′-azo-bis(isobutyronitrile) (a common thermal radical initiator).

The dielectric material described may also comprise other commonly used components, including fillers, adhesion promoters, mold release agents, surfactants, colorants, stabilizers, anti-oxidants, flame retardants, film forming additives, and similar additives known to those skilled in the art.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. A method of making an electronics substrate, comprising:
(i) depositing a material, having a first composition and including a polymer, on a base component;
(ii) imprinting a pattern into the material by contacting the material with a die and moving a profile of the die into the material;
(iii) modifying the material while being held in the profile of the die to cause at least partial curing of the material due to a change in composition of the material from the first composition to a second composition;
(iv) removing the die from the material; and
(v) forming electric conductors in trenches of the pattern.

2. The method of claim 1, wherein the material includes at least one of a solvent and plasticizer, and the composition changes from the first composition to the second composition by removal of the solvent or plasticizer.

3. The method of claim 2, comprising repeating (i) to (v) to form additional conductors.

4. The method of claim 3, wherein the same material is used each time (i) to (v) is repeated.

5. The method of claim 4, wherein the material has a Tg above a temperature to which the material is heated to cure the material.

6. The method of claim 2, wherein the solvent is at least one of toluene, xylene, anisole, pyridine, N-methyl-pyrrolidinone (NMP), N,N-dimethylacetamide, N,N-dimethylformamide, cyclohexanone, tetrahydrofuran, cyclohexyl-2-pyrrolidone, and water.

7. The method of claim 2, wherein the plasticizer is at least one of alkyl, halo and alkoxyderivatives of benzene, alkanes, haloalkanes, ethers, and esters.

8. The method of claim 1, wherein the material includes a reactive solvent and the composition changes from the first composition to the second composition by heating and thereby curing the solvent.

9. The method of claim 8, comprising repeating (i) to (v).

10. The method of claim 9, wherein the same material is used each time (i) to (v) is repeated.

11. The method of claim 10, wherein the material has a Tg above a temperature to which the material is heated to cure the material.

12. The method of claim 8; wherein the reactive solvent is at least one of styrene, alpha-methyl styrene, and divinyl benezene.

13. The method of claim 8, wherein the reactive solvent forms polystyrene.

14. The method of claim 8, wherein the reactive solvent is at least one of 1-Alkyl olefins, 1,1-Dialkyl olefins, 1,3-Dienes, styrene, halogenated olefins, vinyl esters, acrylates, methacrylates, acrylonitrile, methacrylonitrile, acrylamide, methacrylamide, vinyl ethers, N-Vinyl carbazole, N-Vinyl pyrrolidone, aldehydes, and ketones.

15. The method of claim 8, wherein the material includes an initiator to cure the material.

16. The method of claim 15, wherein the initiator to cure the material is at least one of 2,2-dimethoxy-2-phenylacetophenone and 2,2′-azo-bis(isobutyronitrile).

17. The method of claim 1, wherein the polymer has reactive functional groups that cause curing of the polymer to cure the material.

18. The method of claim 17, comprising repeating (i) to (v).

19. The method of claim 18, wherein the same material is used each time (i) to (v) is repeated.

20. The method of claim 19, wherein the material has a Tg above a temperature to which the material is heated to cure the material.

21. The method of claim 17, wherein the polymer is an acrylate-functionalized pre-imidized polyimide.

22. The method of claim 17, wherein the polymer is an styrenic-functionalized pre-imidized polyimide.

23. The method of claim 1, wherein the polymer is at least one of polyimide, polybenimidzaole, polyetherimide, polycarbonate, polysulfone, polyethersulfone, polyketone, polyetheretherketone, polyphenlyene oxide, polybenzimide, polybenzoxazole, polycarbonate, polyurethane, polyphosphazene, polyetherketone, polyarylate, polycyclopentadiene, polynorbornene, and polynortricyclene.

24. A method of making an electronics substrate, comprising:
(i) depositing a material, including a polymer and at least one of a solvent and a plasticizer, on a base component;
(ii) imprinting a pattern into the material by contacting the material with a die and moving a profile of the die into the material;
(iii) removing at least some of the solvent or plasticizer from the material while the remainder of the material is held in the profile of the die to cause at least partial curing of the material;
(iv) removing the die from the material; and
(v) forming electric conductors in trenches of the pattern.

25. The method of claim 24, comprising repeating (i) to (v) to form additional conductors.

26. The method of claim 25, wherein the same material is used each time (i) to (v) is repeated.

27. The method of claim 26, wherein the material has a Tg above a temperature to which the material is heated to cure the material.

28. A method of making an electronics substrate, comprising:
(i) depositing a material, including a polymer and a reactive solvent, on a base component;
(ii) imprinting a pattern into the material by contacting the material with a die and moving a profile of the die into the material;
(iii) curing the solvent of the material while the material is held in the profile of the die to cause at least partial curing of the material;
(iv) removing the die from the material; and
(v) forming electric conductors in trenches of the pattern.

29. The method of claim 28, comprising repeating (i) to (v) to form additional conductors.

30. The method of claim 29, wherein the same material is used each time (i) to (v) is repeated.

31. The method of claim 30, wherein the material has a Tg above a temperature to which the material is heated to cure the material.

32. A method of making an electronics substrate, comprising:
(i) depositing a material, including a polymer having reactive functional groups, on a base component;
(ii) imprinting a pattern into the material by contacting the material with a die and moving a profile of the die into the material;
(iii) curing the polymer while the material is held in the profile of the die;
(iv) removing the die from the material; and
(v) forming electric conductors in trenches of the pattern.

33. The method of claim 32, comprising repeating (i) to (v) to form additional conductors.

34. The method of claim 33, wherein the same material is used each time (i) to (v) is repeated.

35. The method of claim 34, wherein the material has a Tg above a temperature to which the material is heated to cure the material.
